(19) United States
(12) Patent Application Publication
(10) Pub. No.: US 2023/0117191 A1
(43) Pub. Date: Apr. 20, 2023

(54) DETECTING TEMPERATURE OF A TIME OF FLIGHT (TOF) SYSTEM LASER

(71) Applicant: Analog Devices International Unlimited Company, Limerick (IE)

(72) Inventors: Erik D. Barnes, Cambridge, MA (US); Junhua Shen, Wilmington, MA (US); Alberto Marinas, El Puig (ES); Jonathan Ephraim David Hurwitz, Edinburgh (GB); Sivanendra Selvanayagam, Abingdon (GB)

(21) Appl. No.: 17/906,238

(22) PCT Filed: Mar. 12, 2021
(86) PCT No.: PCT/EP2021/056347

§ 371 Date: Sep. 13, 2022

Related U.S. Application Data
(60) Provisional application No. 62/989,114, filed on Mar. 13, 2020.

(51) Int. Cl. H01S 5/00; G01S 7/497; H01S 5/042

(52) U.S. Cl. CPC H01S 5/0021; G01S 7/497; H01S 5/0428

(57) ABSTRACT

Monitoring temperature of a laser diode and adjusting usage of the laser diode based on the monitoring information. The method of monitoring includes using a laser driver circuit to drive the laser diode to deliver multiple test current stimuli at different times related to the laser driver issuing one or a burst of illumination pulses. A differential measurement can be made between at least two of the test current stimuli. The differential measurement can be used to determine an indication of the heating or health of the laser diode in the system or of the laser system as a whole.

### CLAIM OF PRIORITY

This patent application claims the benefit of priority of Erik D. Barnes et al. U.S. Provisional Patent Application Ser. No. 62/989,114, entitled “DETECTING TEMPERATURE OF A TIME OF FLIGHT (TOF) SYSTEM LASER,” filed on Mar. 13, 2020 (Attorney Docket No. 3867.733PRV), which is hereby incorporated by reference herein in its entirety.

### TECHNICAL FIELD

This document pertains generally, but not by way of limitation, to accuracy for powering a laser in Time of Flight (ToF) systems (e.g., for range-finding or determining position or shape of an object in 3D).

### BACKGROUND

It can be difficult to regulate the temperature of a laser diode. Variations in laser diode temperature can affect laser light emission efficiency and can result in wavelength shift of the emitted laser light. This, in turn, can affect accuracy of a Time Of Flight (TOF) system, LIDAR system, or other system using a laser diode.

### SUMMARY

Time Of Flight systems can be used in multiple applications, such as for precisely determining 3D position or shape of one or more objects. One of the key building blocks of a TOF illumination system is a powerful laser diode that can emit light at a desired frequency. A portion of this emitted light can be reflected back. Such reflected light can be used for providing information about the objects, such as distance or depth. Laser diode performance can be a key component for obtaining a precise distance or depth calculation. The high power involved can cause self-heating of the laser diode, which can affect laser diode performance and power efficiency. Therefore, being able to accurately sense the temperature of this laser diode device may help allow improved or optimized control of the emitted laser diode light output power, such as can help with more precise 3D capture of information about the one or more objects. The amount of self-heating can be indicative of wear or a fault developing in the laser or in the thermal connection of the system. Long term exposure to laser diode heating peaks can lead to lifetime drift that may benefit from compensating the system or alerting the user.

This document describes, among other things, a technique that can take determine and use a temperature of the laser diode, such as to help improve overall system performance and resilience.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1: Schematic diagram illustrating an example of a circuit of the device.

FIG. 2A: Graph detailing relationship of current and temperature over time for a TOF illumination system.

FIG. 2B: Graph detailing relationship of current and temperature over time for a TOF illumination system in which the laser diode is pre-biased.

FIG. 3: Flow chart of an example of a method for measuring temperature using at least two current stimuli.

FIG. 4: Flow chart of an example of a method using at least three measurement current stimuli.

FIG. 5: Flow chart of an example of a method using multiple current measuring stimuli.

FIG. 6: Flow chart of an example of a method.

### DETAILED DESCRIPTION

This document describes a very low-cost and robust way of measuring laser diode temperature. This document is focused on the temperature measurement aspects of a ToF or other LIDAR illumination systems. Measuring the temperature of the laser is useful for a many reasons including for tuning the input power based on the optical power that is output by the system and self-heating or other aspects of the laser involved with maintaining the health of the laser system. The laser in such systems can be operated at a low duty cycle. For example, in an Indirect TOF illumination system, the illumination period may provide a burst of light, such as a 100 microsecond illumination pulse burst every 1 millisecond, (e.g., 10% duty cycle). During that illumination pulse burst, the light can be modulated at a modulation frequency of many MHz (e.g., at a modulation frequency between 10-500 MHz). In a pulse-based direct TOF illumination system, the burst of pulses may last for up to a few nanoseconds and be repeated at a duty cycle <5%, for example an illumination pulse burst of 2 nanoseconds with the burst occurring every 100 nanoseconds. The laser diode and the laser diode current driver can get hot during the illumination period, such as during a burst of illumination pulses, and can cool in between bursts of illumination pulses. The performance and lifetime of the laser diode can be heavily linked to both the ambient temperature that the system reaches (which is a combination of the external ambient and the local increased average temperature of the laser and laser driver) and the temperature that the laser reaches during one or a burst of illumination pulses.

One of the challenges is to know the temperature of the laser during illumination, which can be complicated by the thermal resistance between the surface of the laser and the rest of the assembly. This thermal resistance causes local self-heating and there can be rapid changes in the local temperature at or near the laser diode or the laser driver during (when it heats up) and after (when it cools down) illumination, when significant power is dissipated in generating light via the laser.

The laser electrically includes or consists of a laser diode. At least two laser diode driver current pulses can be issued to the laser diode, at the same or different driver current levels, and the corresponding response voltages to such pulses can be measured. The differential between the response voltages can be used for determining a representative temperature indication of a laser diode during illumination, which, in turn is indicative of the change in the temperature of the laser diode above the ambient temperature of the environment.

One technique can be based on a general equation of such a diode in which a voltage drop difference at two different diode current settings is proportional to temperature. The simplified equation of the diode voltage across it is

$$V = n * {V}_{T} * ln ( \frac{I}{{I}_{s}} )$$

Therefore, by performing two measurements of this voltage, e.g., V_{H} and V_{L}, such as for two different diode current values, I_{H} and I_{L}, the resulting voltage difference is proportional to a thermal voltage, V_{T}. The thermal voltage is proportional to temperature. This equation can be solved for the diode temperature, which is a component in the thermal voltage, V_{T}.

$${V}_{H} - {V}_{L} = n * {V}_{T} * ln ( \frac{{I}_{H}}{{I}_{L}} )$$

This temperature measurement technique can be used in the ToF circuitry without requiring extra driver circuitry. The measurements can be performed using the laser diode driver that is sending current pulses to the laser diode, with or without such current pulses being converted by the laser diode to light. The temperature monitoring measurements can be done with the current pulses also being set to a value that is below the threshold value for emitting light from the laser diode. To account for the voltage drop that is a function of any parasitic resistance inside the laser diode or in the wiring routing toward and near the laser diode, it is possible to measure with an additional different current pulse (e.g., having a different current pulse level) and to solve or account for the additional I*R voltage drop component of the voltage measured.

Measuring the laser diode in this way can provide an absolute measure of temperature at a point of time. Measuring immediately before or at the beginning of the laser pulse burst illumination period can provide an approximate measure of the ambient temperature, assuming there is a low duty cycle of the illumination period separating such laser pulse burst from a laser pulse burst of the next illumination period. Measuring immediately after or at the end of the illumination period provides a measure the temperature of the laser with the effect of self-heating due to the energy used for illumination, and the difference can be representative of the average self-heating during the illumination period.

Since the laser diode can have relatively low thermal capacity, the rate of change of temperature can be quite high, particularly after illumination when the laser will cool quickly. This poses a difficulty for an accurate measurement of the laser diode temperature using two different current pulses, as they will be issued (and corresponding response voltages measured) at two different points in time and the laser diode may have heated or cooled in between those points in time. To partially compensate for this error in time from cooling or heating, it is possible to repeat the measurement but issuing the test current pulses with the different current pulse levels I_{L} and I_{H} swapped in time to partially cancel any linear change in temperature due to temporal offset.

Another approach to reduce or minimize this slope effect is to reduce the number of measures needed and to make a measure of the change in temperature due to illumination by comparing the voltage (V_{H1}) measured with a first current pulse at a first current level (I_{H}) before illumination with the response voltage (V_{H2}) measured with the same stimuli current level using a second current pulse issued after the illumination period of one or a burst of laser pulses, and calculate the change in temperature by using the difference in response voltages V_{H} voltage (V_{H1}−V_{H2}) to estimate the change in the thermal voltage V_{T} of the laser diode. This can be combined with a separate measure of the ambient temperature (e.g., using a thermometer, thermocouple, thermistor, or other such direct temperature sensor) to then determine approximately the absolute temperature of that the laser diode reaches during illumination.

One way to obtain an approximate measure of the ambient temperature is outlined earlier to make a measure using the two different stimuli current I_{H} and I_{L} before the illumination. This reduces the number of stimuli to be measured to be 3 (e.g., 2*I_{H} and 1*I_{L}) as opposed to 4 (e.g., 2*I_{H} and 2*I_{L}). Another method is to measure the ambient temperature of a circuit or device that is closely coupled to the laser, such as using an embedded temperature sensor within the laser driver circuitry, or an external resistive temperature detector (RTD) measured by the laser driver circuitry. In this case the ambient temperature measure can be made in parallel and not necessarily synchronous with the measurement of the change in temperature from the change in V_{H} measure from the laser diode before and after the laser illumination period, reducing the time critical measures from the laser diode to being done with 2*I_{H} to at least one measurement immediately before and one measurement either immediately or soon after the illumination period of one or a burst of illumination pulses.

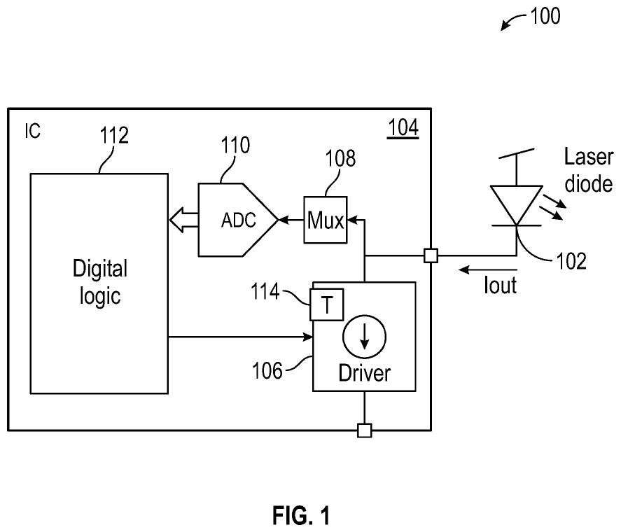

FIG. 1 shows an example of portions of a ToF illumination system 100. The ToF illumination system 100 can include a laser source such as a laser diode 102, such as can be connected to controller circuitry 104. The controller circuitry 104 can include a laser driver 106, such as a current sink. The laser driver 106 can be connected to the laser driver 102, such as to a cathode of the laser diode 102. The controller 104 can include, among other things, a multiplexer 108 such as for routing signal measurements to an analog-to-digital converter (ADC) 110. The MUX can be used to share the ADC with other functions that may need measuring in the system such as the VCSEL supply voltage (anode of the VCSEL). The resulting digitized measured signals can be further signal-processed, such as by digital signal processing circuitry 112, a control output 114 of which can be used to control the driver 106, such as in response to a measured operating or health characteristic of the laser diode 102.

For example, the driver 106 can be controlled to deliver multiple specified test currents, such as at different levels I_{H} and I_{L}, to the laser diode 102 as well as the laser drive currents to provide illumination. The controller 104 can be configured to measure the corresponding respective responsive voltages, V_{H} and V_{L}, that correspond to those respective specified test currents, I_{H} and I_{L}. One or both of the measured response voltages or measured test currents can be received at different distinct inputs. Response voltages can be measured at the cathode node of the laser diode 102. The laser diode 102 can also include an anode node, such as can be coupled to a voltage supply or reference voltage. As the supply or reference may be varying under different loads, capturing V_{H} and V_{L} with respect to the anode voltage to remove this source of error. This may be done through the MUX 108, or alternatively, not shown a sampling circuit that creates the difference of the anode and cathode voltages before it is digitized. Other analog processing steps are possible such as a circuit that would take the difference between V_{H} and V_{L} before digitization. These two techniques can be combined thereby using both the MUX 108 and a sampling circuit (not shown) to determine the difference between V_{H} and V_{L} before digitization.

Measuring the response voltage can include driving the current delivered to the laser diode 102 at one or more specified current levels above the light emitting threshold of the laser diode 102. Alternatively, or additionally, measuring the response voltage can include driving the current delivered to the laser diode 102 at one or more specified current levels that are below the light emitting threshold of the laser-diode 102. The drive current levels below the light emitting threshold can be called the “sub-illumination” current levels. The response voltage can measured using circuitry that can include the multiplexer 108, which can include analog front end (AFE) circuitry, and an analog-to-digital converter 110. These circuitry components can be integrated on an integrated circuit controller 104 into the system 100. Alternatively, these components can be co-located or co-packaged on the same circuit board or multi-chip module, or can include separate discrete connected components of the system 100.

As mentioned, the current to the laser diode 102 can be driven or otherwise provided using one or more specified test stimuli currents that are at sub-illumination levels of the laser diode 102. Running the test stimuli at sub-illumination can help save power and can help avoid energizing the laser diode 102 to output illumination light at energy levels sufficient to receive reflected light for use in ToF calculations. Therefore, these test stimuli measurements can be performed “transparent” to the ToF measurements using the system 100 and need not affect the measurements of TOF illumination system 100.

Sometimes, the laser diode 102 can be pre-biased, e.g., before illumination, such as to reduce the turn-on transient voltage and current characteristics. One or more of the test current stimuli can be delivered and the response voltages measured during such pre-biasing. In an example, at least one of the two test current stimuli is taken before the illumination pulse and at least one of the two test current stimuli is taken after the illumination pulse. Heating and cooling effects of operating the laser happen with relatively fast time constants during illumination. This could lead to errors or differences in measurements from using different times at which the response voltage is measured even when the two response voltage measurements are both done either before or after the illumination pulse. By alternately swapping multiple pairs of higher-current and lower-current test stimuli and response voltage measurements, the effect of a temporal cooling gradient of the laser diode 102 can be mitigated, such as using the pair-wise differential measurements. Additionally, or alternatively, information about this cooling gradient can be otherwise factored in or used to improve the temperature measurements that can be obtained using differential voltage responses to individual pulses in pairs of test current stimuli.

In an example, first and second response voltage samples can be performed concurrently, simultaneously, or near-simultaneously, such as without change in time between the first and second samples of the response voltage. For example, near-simultaneous response voltage measurements can be performed by measuring the first voltage response across the laser diode 102 before a first illumination burst and measuring the collector voltage across the laser diode 102 before a second illumination burst. The illumination burst can include a set of multiple illumination pulses that can occur during an illumination activity cycle. Successive illumination activity cycles can be separated from each other, such as by a set period of time during which no illumination pulses occur. The duty cycle of this activity can be less than 20%, less than 10%, less than 5% or less than 1%.

Additionally, or alternatively the ambient temperature of the laser diode 102 can be directly measured such as using an optional temperature sensor 114 such as can be attached to or co-located with the laser or the laser driver circuitry. The temperature sensor 114 can be embedded in the silicon of the driver 106 or can be external to the laser driver and diode but within the same package or assembly. Measuring or deriving the laser driver temperature can also be used as a proxy for the temperature of the laser diode 102. The temperature sensor 114 can include one or more of a resistor temperature sensor, a thermistor, a thermocouple, or other temperature measurement component. Additionally or alternatively, the change in temperature of the diode 102 during illumination can be indirectly determined using the measured (or programmed) laser-driver 106 current and resultant response voltage measurement, such as before and after the illumination by the diode 102, either alone, or in combination with a temperature measured elsewhere in the system, such as using the separate temperature sensor 114. In this case, one technique to measure before the illumination with a first current stimuli and measure after the illumination with the same current stimuli and use the change in voltage to calculate the self-heating and combine this measurement with the ambient or absolute temperature measurement to calculate the temperature the laser reached during illumination. Another technique is to measure before the illumination with a first current stimuli and a different second currents stimuli to calculate an estimate of the absolute ambient temperature and to measure after the illumination with at least one of the two same current stimuli and use the change in voltage to calculate the self-heating, and combine this measurement with the first calculation of ambient temperature measurement to calculate the temperature the laser reached during illumination.

One or more indications of the measured laser temperature can be used as part of a laser diode health indication of the system. Alerts may be presented to the user if particular criteria or threshold temperatures are met. The health indication can be estimated over multiple laser diode 102 illumination pulses or over multiple operation cycles of the laser diode 102. The health indication can be used to determine if a number of illumination pluses or illumination bursts should be suppressed or inhibited for either efficiency or safety reasons. This can be done in response to criteria given to the system 104 or another criterion determined by the user. An operation cycle of the laser diode 102 can include a time period when the laser diode 102 is outputting illumination to when the laser diode 102 ceases outputting illumination and is thereby placed in an “off” state. The health indication can be taken over a sequential number of one or more operation cycles or over a specified period of time, such as over a period of years. The health indication can also be used for alerts regarding the diode 102 or the system 104.

The controller 104 circuitry of the ToF illumination system 100 can include digital signal processing circuitry 112, such as for post-processing of the measured first and second response voltage differentials. The post-processed signals can be used for calibration or closed-loop feedback such as to control the current driver 106. Such control can include correcting or adjusting one or more settings of the current driver, such as current amplitude, pulse duration, delay, harmonic content, repetition rate, or the like. This can help accommodate or correct self-heating effects of the laser diode 102 that can degrade the performance of the system 100 over time.

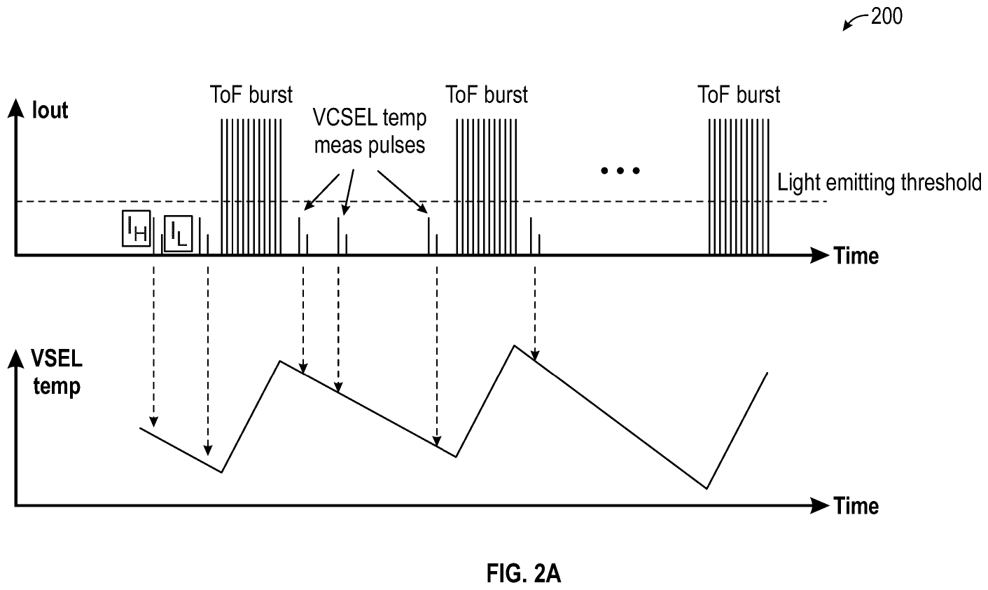

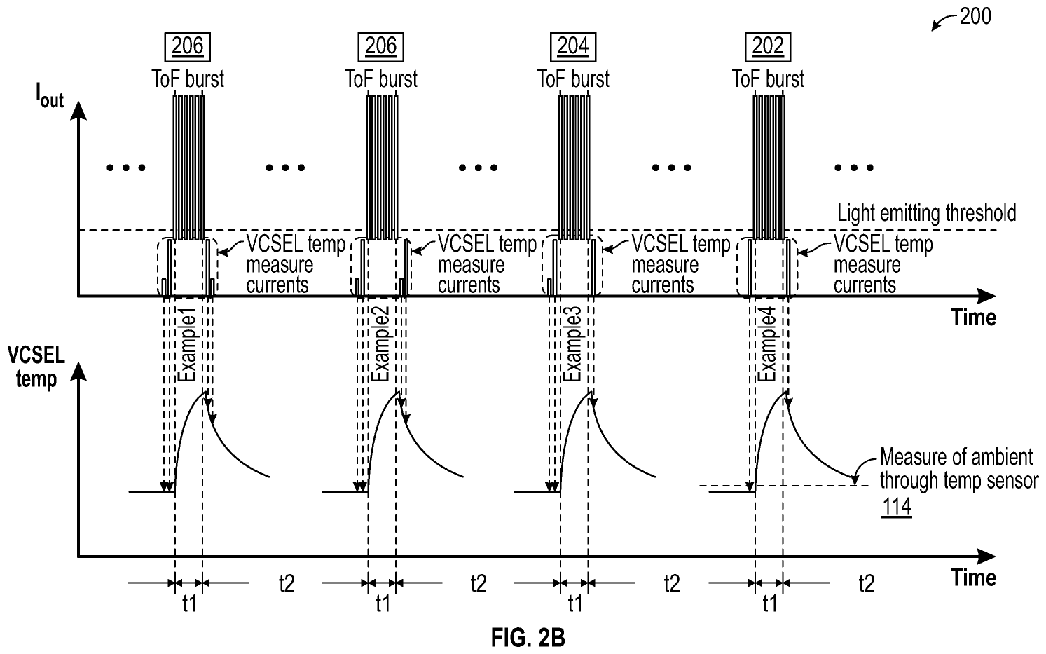

FIGS. 2A and 2B includes graphs of driver current vs. time and response voltage vs. time, which illustrates an example of the timing of the measurements that can be performed using the circuitry shown in FIG. 1. In FIG. 2A, the laser diode 102 can be driven by the laser driver 106, such as using sub-illumination test current stimuli. The controller 104 circuitry can also be used to control the driver 106 to drive the laser diode 102 at current levels above the light emitting threshold for illuminations by the laser diode 102. These illuminations can be used by the TOF illumination system 100 for target object distance or depth determination such as using a photodetector or imager to detect a reflected response to the illuminations. The laser diode 102 cathode node voltage measurements, or the resulting VSCEL temperature measurements, can be made in response to two different specified sub-illumination test current levels, which need not result in the laser diode 102 emitting light and therefore can be “invisible” or “transparent” at the TOF illumination system 100. The illumination period of the TOF burst may last for time t1 and this be repeated after time t1+t2, such that the duty cycle of operation is t1/(t1+t2). The duty cycle of operation can be less than 20%, less than 10%, less than 5%, less than 1%, and leads to a temperature differential at the VCSEL shown in the curve below, that is non constant and reflects the local self-heating in the VCSEL in response to the energy of driving it for the illumination period and the subsequent cooling before the next illumination period. Example 1 of FIG. 2B, shows an example of one of the ways to determine the laser two different laser diode 102 current values, e.g., I_{H} and I_{L}, produce the resulting response voltage difference that is proportional to a thermal voltage, V_{T}. Therefore, the difference between the measured V_{H} and V_{L} is proportional to the temperature of the laser diode 102 in the system 100. This can be performed once before illumination to measure the steady state ambient and once after the illumination period to measure the new temperature such as to calculate or determine the rise in temperature.

The illumination and sub-illumination laser diode 102 temperature measurement process can be controlled by the controller 104. The controller 104 can control when to change the driver 106 operation from higher level driver currents for illumination by the laser diode 102 to lower level sub-illumination test currents. A multiplexer 108 or other analog front end (AFE) and an analog-to-digital converter (ADC) 110 can be used to capture these two measured voltages in response to the two different forced sub-illumination driver test currents at two different points in time, such as with respect to a power supply or ground voltage VDD or VSS, the anode of the VCSEL or another reference, and the controller 104 can be used to compute the difference between the two response voltages. The measured differential voltage response can be used to provide an indication of the temperature of the laser diode (VCSEL temperature). Such information can be stored or logged to provide an indication of a change in temperature of the laser diode 102 over time, or to provide an indication of the ongoing health of the laser diode 102 in the system 100. The process can measure the temperature just before and just after a series or burst of ToF illuminations by the laser diode 102 or during a “rest” or inactive period between such ToF illumination bursts, such as shown in FIG. 2A. In Examples 1 and 2 in FIG. 2B, the controller 104 can also interleave two different test current stimuli levels, such as can be used for making two different laser diode 102 cathode response voltage measurements after the illumination period in order to compensate for the temperature gradient from heating or cooling. In another example, two measures of V_{H} can be made either side of the measurement of V_{L} after the illumination period. This can help cancel to a first-order effects of the temperature gradient while measuring the different stimuli in time. Other forms of temporal interleaving of pulses of same or different current pulse levels are possible, including changing the order of different level pulses in a pair of pulses on successive illumination periods and averaging the measurements.

In FIG. 2B, in example 3, at 204, a differential measurement is made before illumination with V_{H1} and V_{L}, to calculate the ambient and then make a second measurement of V_{H2} after the illumination period and to use the difference in V_{H1} and V_{H2} to calculate the change in temperature. This approach can help reduce or minimize the number of measurements to be included after the illumination period and minimizes the cooling period in taking the measurements. In a similar example, a measurement of V_{L2} could be made after the illumination period instead of V_{H2} and the difference between V_{L} and V_{L2} are used to calculate the change in temperature.

In FIG. 2B, in example 4, at 202, the ambient temperature of the TOF illumination system 100 can be taken elsewhere, for example using an embedded temperature sensor in the laser driver, or with an external RTD using temperature sensor circuit 114, and the difference in temperature of the VCSEL after illumination can be determined by just two identical measurements before and after the illumination, V_{H1} and V_{H2}. Many other schemes can be scheduled for example to include measurements at 3^{rd} stimuli level such as to remove the effects of I*R in the parasitic resistances of the diode and measurement system.

Measurements can be scheduled at times at which the system 100 is not driving the high current ToF illumination pulses, such as shown in FIG. 2A and FIG. 2B. For example, the temperature-indicating voltage measurements can be performed just before and just after a scheduled ToF burst of multiple illumination pulses. Such temperature measurements can provide useful information about laser diode self-heating, such as due to that particular burst of multiple illumination current pulses. Such temperature information can then be processed, such as by the controller 104 and can be used to control one or more modulation or other characteristics of subsequent illumination pulses by controlling the driver 106 accordingly. The temperature information can also be used in post-processing of the received ToF reflected light information, such as to allow for correction of one or more self-heating effects of the laser diode 102, such as wavelength deviation, delay, harmonic content etc.

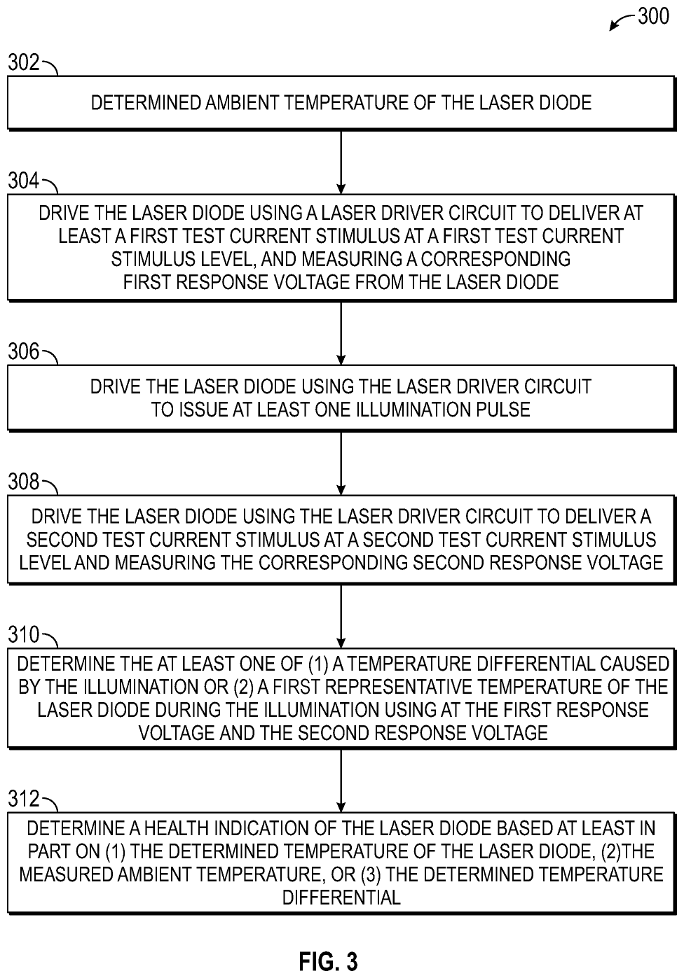

FIG. 3 shows a block diagram example of a method of using the system 100 of FIG. 1. At 302, the ambient temperature is determined. This can be done by using a temperature detector 114, one or more measurements can be made an ambient temperature of at least one of the laser diode 102 or the driver 106. Ambient temperature of the laser diode 102 can be obtained, either directly measured by use of an optional direct temperature sensor 114 attached to or co-located with at least one of the laser diode 102 or the driver 106 or measured by one or more indirect measurements, such as using differential or other multiple voltage responses. In other examples below the test current stimuli can be used to determine the ambient temperature without having to incorporate a temperature detector 114, making the temperature detector 114 optional.

At 304, the driver circuit 106 can be used to drive the laser diode 102 to deliver at least a first test current stimulus at a first current stimulus level and to measure a corresponding first response voltage from the laser diode 101. In some examples, either the first or the second test current stimuli can include or occur during a pre-bias laser stimulus. The specified driver 106 currents can be provided to the laser diode 102 at sub-illumination levels of the laser diode 102, that is, below the light emitting threshold.

At 306, using the laser driver 106 to drive the laser diode 102 at least one ToF illumination driver current pulse (or burst) can be delivered in temporal association with the first and second test current stimuli.

At 308, the laser diode 102 can be drive using the laser driver circuit 106 to deliver at least a second test current stimulus at a second current stimulus level. A corresponding second response voltage from the laser diode 101 can be measured using response voltage measurement circuitry. The first test current stimulus and the second test current stimulus can be temporally separated by the illumination pulse (or series or burst of such illumination pulses) or they can be obtained without being separated by such illumination pulses or bursts. In an example, the test current stimuli can be separated by one or more illumination pulses or bursts, and the first and the second test current stimulus are issued at the same current level.

At 310, a differential measurement of first and second response voltages to first and second test current pulses can be obtained. For example, the burst of illumination pulses can occur over a period of 100 milliseconds that happen at a burst frequency of 400 Mhz. One or both of the sequence of illumination pulses and the burst frequency of the illumination pulses may be adjusted or controlled, such as using an indication of laser diode 102 temperature or health.

At 312, a health indication of the laser diode 102 can be based at least in part on one or both of (1) the measured or derived ambient temperature or (2) the determined differential response voltage measurement. The health indication can be based on an average or other central tendency of multiple such measurements. Multiple sets of differential measurements can be made, such as to determine either a heating indication of the laser diode 102 during operation or a health of the laser diode 102, or both. The determined health indication can be used to establish a baseline for the illumination power the laser diode 102, such as being used in normal operating conditions. As the laser diode 102 is used over a period of time, one or both of the measured ambient temperature or the differential measurement of the first and second response voltages can be used by the system 100 to adjust the illumination power of the laser diode 102 such as by adjusting the driver current of the laser driver 106. One or more alerts can be issued, displayed, or sent to a human or other user of the system 104, such as when the health indication of the laser diode 102 meets one or more particular criteria that can either be set by the system 100 or by the user. Such criteria can include an indication of heating or overheating of the laser diode 102 or system 100 when in use. The health indication of the laser diode 102 or system 100 can be used, for example, to suppress the next illumination pulse or to reconfigure the settings for the burst of illumination pulses coming from the laser diode 102. The health indication of the laser diode 102 or system 100 can be used to change a specified period of time between bursts of illumination pulses or to adjust the number of illumination pulses within a particular burst of the illumination pulses.

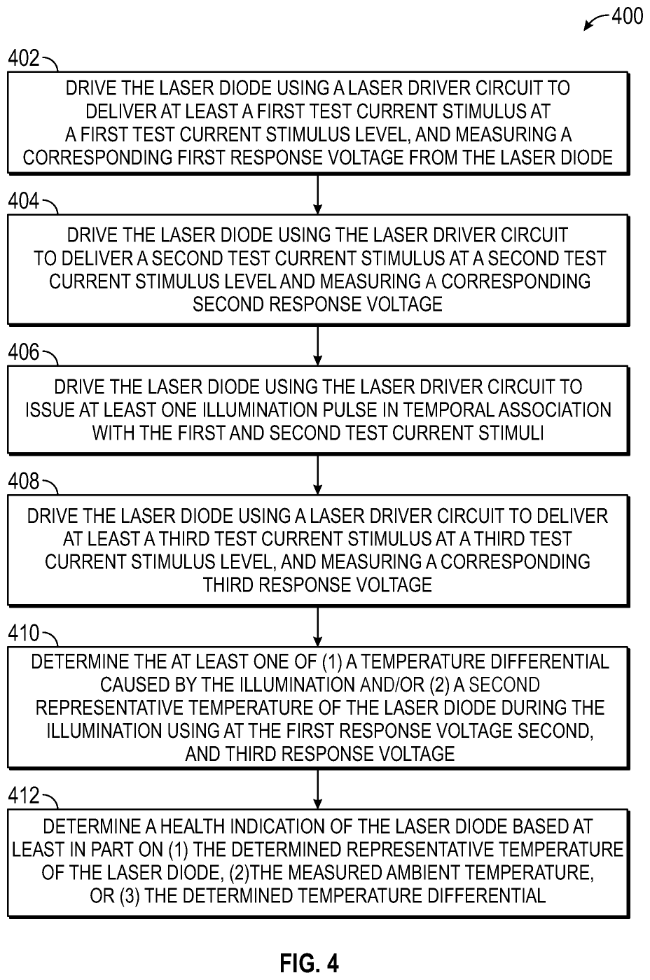

In FIG. 4 at 402, the laser diode 102 can be driven using a laser driver 106 to deliver at least a first test current stimulus at a first test current stimulus level and response voltage measurement circuitry can be used for measuring a corresponding first response voltage from the laser diode 102. Following the measurement of the first response voltage at 404, the laser diode 102 can be driven using the laser driver 106 to deliver a second test current stimulus at a second test current stimulus level and response voltage measurement circuitry can be used for measuring the corresponding second response voltage. The first and the second test current stimuli can be at driven at current level equal to either I_{H} or I_{L} to produce V_{H} and V_{L} respectively. The test current stimuli can be delivered before driving of a current that is sufficient to create an illumination pulse.

At 406, the laser diode 102 can be driven using the laser driver circuit 106 to issue at least one illumination pulse in temporal association with the first and second test current stimuli.

At 408, the laser diode 102 can be driven using a laser driver circuit to deliver at least a third test current stimulus at a third test current stimulus level and measuring a corresponding third response voltage. The third response voltage can be driven by the driver 106 at either I_{H} or I_{L} in order to measure a correspond voltage. At 410, this third response is used with either the first or second response voltage in order to determine a temperature differential caused by the illumination or a representative temperature of the laser diode can be determined. The representative temperature can used a derived measurement of the ambient temperature that uses the first and second response voltage and the differential temperature using the third response voltage and either the matching first or second response voltage in order to determine the temperature of the diode 102.

At 412, a health indication of the laser diode 102 is determined based at least in part on (1) the determined temperature of the laser diode, (2) the measured ambient temperature, or (3) the determined temperature differential. As explained above the health indication of the system 100 can be determined looking at the temperature of the laser diode, the ambient temperature and other derived and measured values such as by the methods described herein.

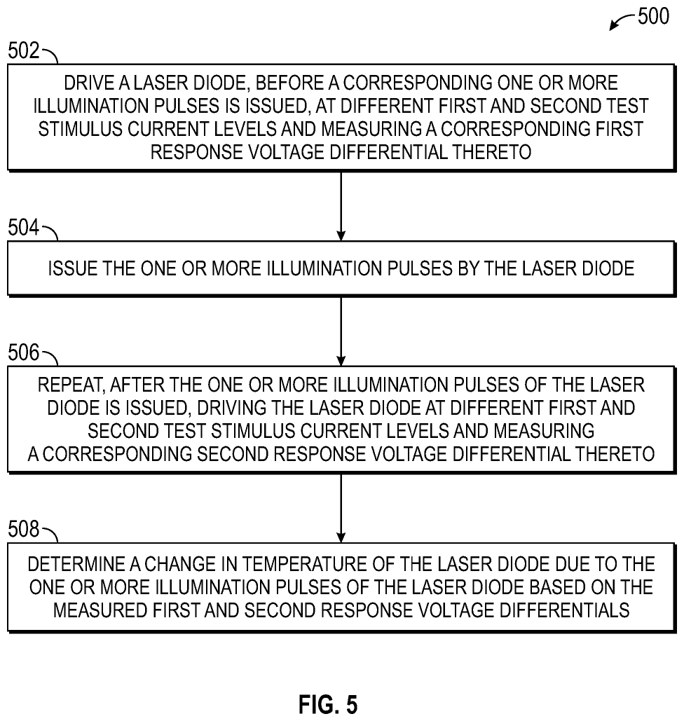

FIG. 5 shows an example of portions of a method of using the system 100 of FIG. 1, such as can be combined with or used separately from one or more aspects shown in FIG. 3. At 402, the laser diode 102 can be driven by test current stimuli, before a corresponding one or more illumination pulses is issued. The test current stimuli are at two different driver current levels I_{H} and I_{L}. The test current stimuli can be issued at different first and second test stimulus current levels. Corresponding first and second response voltages can be measured, such as to provide a differential responses to thereto as the first response voltage. Either the first or the second test current stimuli can, in an example, include a pre-bias laser stimulus. The transient voltage and current response delay of the laser diode 102 can be reduced such as by using pre-biasing first or second response current stimuli. The driver current can be provided to the laser diode 102 at specified test currents that are at sub-illumination levels of the laser diode 102.

At 504, driver current can be provided to issue one or more illumination pulses (e.g., series or burst of illumination pulses) by the laser diode 102. In an example, the burst of illumination pulses can occur over a period of 100 ms that happen at a frequency of 400 Mhz, either of which can be adjusted at least in part using the temperature measurements or health indication determined, such as described herein. The measurement of the first response voltage can be separated by one or more illumination pulses or bursts.

At 506, after issuing one or more illumination pulses of the laser diode 102 a repeat of the first and second test stimulus current levels may be done, and a second responsive voltage differential may be determined. The first and second test stimulus current levels can be issued at sub-illumination test current stimuli and at different current levels. The two different specified current levels can be driven in the same sequence as they were at 504 or they can be reversed in sequence. For example, if before the illumination pulse or illumination burst the test currents were first driven I_{H} followed by I_{L}, after illumination the second response current levels may first drive I_{L} followed by I_{H}. In a further example in order to compensate for the temperature gradient from heating or cooling two measurements of at the first test current level are made either side of the measurement of the second test current level after the illumination period in order to first order cancel the effect of the temperature gradient.

At 508, a change in temperature of the laser diode 102 due to the one or more illumination pulses of the laser diode 102 can be determined, such as based on the measured first and second response voltage differentials. The temperature change or change in first and second response voltage differentials can be used to determine a health indication of the laser diode 102 or of the system 100 as a whole. The health indication of the system 100 can be determined over multiple sets of pulses or over multiple illumination cycles over a period time. An illumination characteristic such as burst issue time or burst frequency can be a adjusted, such as can be based at least in part on the heating of the laser diode 102 during a previous illumination cycle. This can help inhibit or prevent the laser diode 102 from overheating.

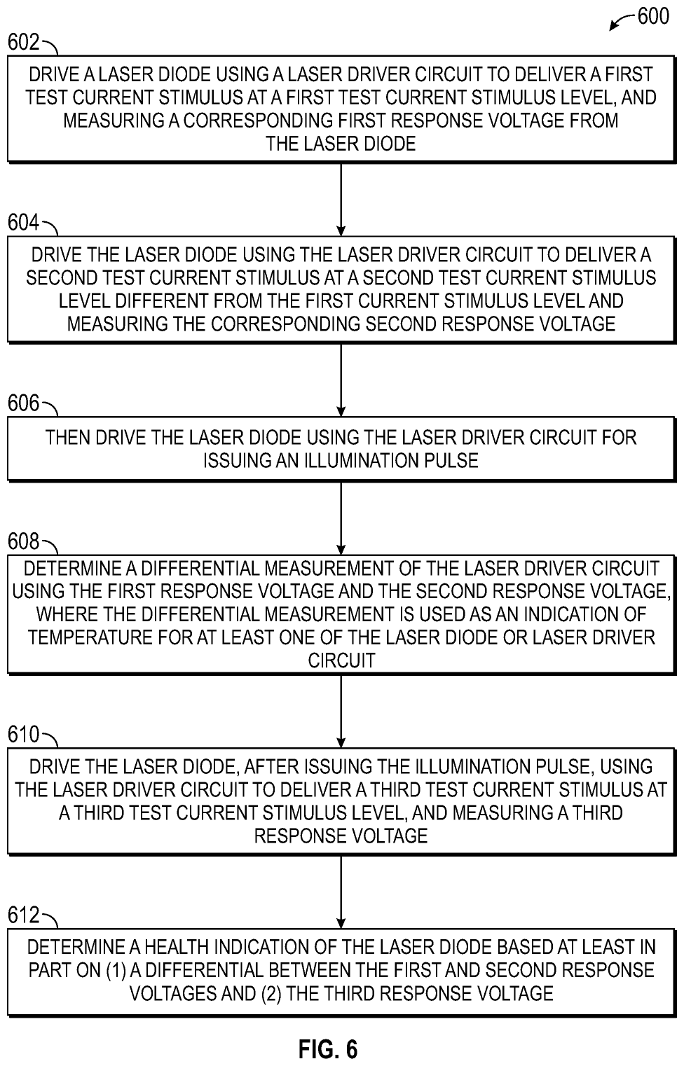

FIG. 6 shows an example of portions of a method of using the system 100 of FIG. 1, such as can be combined with or used separately from one or more aspects shown in FIGS. 3-4. At 502, using a laser driver 106 to drive a laser diode 102, a first sub-illumination test current stimulus can be delivered at a first test current stimulus level, and a corresponding first response voltage from the laser diode 102 can be measured.

At 604, a second test current stimulus can be delivered by the driver 106 at a second sub-illumination test current stimulus level different from the first current stimulus level, and the corresponding second response voltage can be measured.

At 606, the laser driver 106 can drive the laser diode 102 for issuing an illumination pulse.

At 608, a differential measurement using the first response voltage and the second response voltage can be obtained. The differential measurement can be used as an indication of temperature for the laser diode 102 or laser driver 106.

At 610, after issuing the illumination pulse or burst, a third test current stimulus can be delivered by the driver 106 at a third test current stimulus level, and a third response voltage can be measured.

At 612, a health indication of the laser diode 102 can be determined, such as can be based at least in part on (1) a differential between the first and second response voltages and (2) the third response voltage.

While the focus herein has been on temperature measurement of a laser diode such as for application in a ToF or other LIDAR object detection or other ranging system, the present approach is also usable and useful in many other applications in which a laser diode is used, and in which measurement or correction for self-heating effects can be used to improve accuracy or efficiency of system operation. Other aspects or examples of such a ToF or LIDAR system such as described in the following patent documents US 2019/0154812, U.S. Pat. Nos. 9,274,202, 10,054,675, US 20180203102, US 20180189977, US 20190113606, U.S. Pat. No. 10,158,211, each of which is incorporated by reference herein.

The above description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

1. A method of using and monitoring a temperature of a laser diode associated with illuminating by the laser diode, the method comprising:
driving the laser diode using a laser driver circuit to deliver at least a first test current stimulus at a first test current stimulus level, and measuring a corresponding first response voltage from the laser diode;
driving the laser diode using the laser driver circuit to deliver a second test current stimulus at a second test current stimulus level and measuring the corresponding second response voltage;
driving the laser diode using the laser driver circuit to issue at least one illumination pulse in temporal association with the first and second test current stimuli; and
determining the at least one of (1) a temperature differential caused by the illumination or (2) a first representative temperature of the laser diode associated with the illumination at least in part using the first response voltage and the second response voltage.

2. The method of claim 1, wherein the first representative temperature is a determined ambient temperature of the laser diode, and further comprising:
driving the laser diode using the laser driver circuit to deliver at least a third test current stimulus at a third test current stimulus level, and measuring a corresponding third response voltage; and
using the determined ambient temperature and the third response voltage to determine a second representative temperature of the laser diode.

3. The method of claim 2, wherein the third test current stimulus is delivered at a like current level as at least one of the first test current stimulus or the second test current stimulus.

4. (canceled)

5. The method of claim 2, further comprising:
driving the laser diode using the laser driver circuit to deliver at least a fourth test current stimulus at a fourth test current stimulus level, different than the third current stimulus level, after the at least one illumination pulse, and measuring a fourth corresponding response voltage; and
determining a third representative temperature of the laser diode using at least the third response voltage and the fourth response voltage.

6. (canceled)

7. The method of claim 1, comprising:
measuring an ambient temperature via a temperature detector; and
determining the temperature differential of the laser diode using the measured ambient temperature and the first and second response voltages.

8. The method of claim 2, further comprising:
determining a health indication of the laser diode based at least in part on at least one of (1) the determined second representative temperature of the laser diode, (2) the measured ambient temperature, or (3) the determined temperature differential.

9. A method of claim 2, wherein the third response voltage is determined, after the illumination pulse; and comprising:
determining a health indication of the laser diode based at least in part on at least one of (1) the second representative temperature before or after the illumination pulse or (2) an indication of the ambient temperature determined using the first and second response voltage.

10. The method of claim 9, comprising establishing or adjusting an illumination power of the laser diode using the determined health indication or the second representative temperature of the laser diode.

11. The method of claim 8, comprising issuing an alert in response to the health indication of the laser diode meets at least one first criterion.

12. The method of claim 8, comprising inhibiting issuing at least one illumination pulse by the laser diode when the indication of health of the laser diode meets at least one second criterion.

13.-17. (canceled)

18. The method of claim 1, comprising issuing an alert when the determined temperature differential or the first representative temperature meets at least one first criterion.

19. The method of claim 1, comprising inhibiting issuing of at least one illumination pulse by the laser diode when the determined temperature differential or the first representative temperature meets at least one second criterion.

20. The method of claim 1, wherein the at least one of determining the temperature differential or the first representative temperature comprises repeating and based thereupon determining an indication of central tendency.

21. (canceled)

22. (canceled)

23. The method of claim 1, wherein at least one of the first test current stimulus or the second test current includes a pre-bias laser stimulus.

24. (canceled)

25. A method comprising:
driving a laser diode, before a corresponding one or more illumination pulses is issued, at different first and second test stimulus current levels and measuring a corresponding first response voltage differential thereto;
issuing the one or more illumination pulses by the laser diode;
repeating, after the one or more illumination pulses of the laser diode is issued, driving the laser diode at different first and second test stimulus current levels and measuring a corresponding second response voltage differential thereto; and
determining a change in temperature of the laser diode associated with the one or more illumination pulses of the laser diode based on the measured first and second response voltage differentials.

26. (canceled)

27. (canceled)

28. The method of claim 25, comprising determining a laser diode health indication of the laser diode is determined over multiple sets of pulses.

29. The method of claim 28, wherein the health indication of the laser diode is further determined over multiple operation cycles to determine an aging indicator of the laser diode.

30. A method comprising:
driving a laser diode using a laser driver circuit to deliver a first test current stimulus at a first test current stimulus level, and measuring a corresponding first response voltage from the laser diode;
driving the laser diode using the laser driver circuit to deliver a second test current stimulus at a second test current stimulus level different from the first current stimulus level and measuring the corresponding second response voltage;
then driving the laser diode using the laser driver circuit for issuing an illumination pulse;
determining a differential measurement of the laser driver circuit using the first response voltage and the second response voltage, wherein the differential measurement is used as an indication of temperature for at least one of the laser diode or the laser driver circuit;
driving the laser diode, after issuing the illumination pulse, using the laser driver circuit to deliver a third test current stimulus at a third test current stimulus level, and measuring a third response voltage; and
determining a health indication of the laser diode based at least in part on (1) a differential between the first and second response voltages and (2) the third response voltage.

31. A device comprising:
a laser diode;
a current driver for providing corresponding current pulses of one or more illumination pulses issued by the laser diode, wherein the one or more illumination pulses are issued by the laser diode at different first and second test stimulus current levels;
circuitry for determining a change in temperature of the laser diode due to the one or more illumination pulses of the laser diode based at least in part on a measured first and second response voltage differentials to respective first and second test current stimulus levels; and
signal processing circuitry for determining a health indication of the laser diode by comparing a representative temperature of the current driver with the change in temperature of the laser diode.

32.-34. (canceled)

35. The device of claim 31, further comprising controller circuitry for post-processing of the measured first and second response voltage differentials for controlling the current driver for correcting or compensating for one or more self-heating effects.
